(19) United States
(12) Patent Application Publication
(10) Pub. No.: US 2026/0052777 A1
(43) Pub. Date: Feb. 19, 2026

(54) INTEGRATED CIRCUIT COMPONENT, PROCESSOR, AND SYSTEM ON CHIP

(71) Applicant: Alibaba (China) Co., Ltd., Hangzhou (CN)

(72) Inventors: Han XU, Beijing (CN); Shuangchen LI, Sunnyvale, CA (US); Zhe ZHANG, Beijing (CN); Youwei ZHOU, Beijing (CN); Xuechao WEI, Beijing (CN); Dimin NIU, Shanghai (CN); Hongzhong ZHENG, Los Gatos, CA (US)

(21) Appl. No.: 19/368,852

(22) Filed: Oct. 24, 2025

Related U.S. Application Data
(63) Continuation of application No. PCT/CN2024/089852, filed on Apr. 25, 2024.

(30) Foreign Application Priority Data
Jun. 7, 2023 (CN) 202310672654.8

(51) Int. Cl. H10D 88/00; H01L 23/00; H01L 23/48; H01L 25/065; H01L 25/16; H10B 80/00

(52) U.S. Cl. CPC H10D 88/00; H01L 23/481; H01L 25/0657; H01L 25/16; H10B 80/00; H01L 24/08; H01L 2224/08145

(57) ABSTRACT

Embodiments of the present disclosure provide an integrated circuit component, a processor, and a system on chip. The integrated circuit component includes three wafer layers. Each of the wafer layers includes a front side and a back side. The front side of a first wafer layer and the front side of a second wafer layer are stacked, and the front side of the second wafer layer and the back side of a third wafer layer are stacked. The three wafer layers are interconnected through a through-silicon via, a re-distribution layer, and hybrid bonding. The second wafer layer or a slow wafer layer among the three wafer layers includes a direct memory access master controller. The direct memory access master controller is configured to receive a data transmission request sent by a slave terminal of another wafer layer, and cause a slave terminal of the second wafer layer or the slow wafer layer among the three wafer layers to perform data transmission.

### CROSS-REFERENCE TO RELATED APPLICATIONS

The present disclosure claims priority to Chinese Patent Application No. 202310672654.8, filed with the China National Intellectual Property Administration on Jun. 7, 2023, and entitled “INTEGRATED CIRCUIT COMPONENT, PROCESSOR, AND SYSTEM ON CHIP”, which is incorporated herein by reference in its entirety.

### TECHNICAL FIELD

Embodiments of the present disclosure relate to the field of computer technologies, and in particular, to an integrated circuit component, a processor, and a system on chip.

### BACKGROUND

3D (three-dimensional) wafer-level packaging refers to a packaging technology that stacks two or more wafer layers in a vertical direction in a same package without changing a size of the package. Main characteristics of the 3D wafer-level packaging include multi-function, high performance, large capacity, and high density. Therefore, an integrated circuit component with the 3D wafer-level packaging can provide a larger on-chip storage capacity to meet a requirement for calculation of a foundation model. The 3D wafer-level packaging has become a trend of current technology development.

### SUMMARY

The present disclosure implements a 3D interconnected data flow architecture in an integrated circuit component with 3D wafer-level packaging.

Embodiments of the present disclosure provide an integrated circuit component, a processor, and a system on chip, to at least partially resolve the foregoing problem.

According to a first aspect of the embodiments of the present disclosure, an integrated circuit component is provided, including three wafer layers. Each of the wafer layers includes a front side and a back side. The front side of a first wafer layer and the front side of a second wafer layer are stacked, and the front side of the second wafer layer and the back side of a third wafer layer are stacked. The three wafer layers are interconnected through a through-silicon via, a re-distribution layer, and hybrid bonding. The second wafer layer or a slow wafer layer among the three wafer layers includes a direct memory access master controller. The direct memory access master controller is configured to receive a data transmission request sent by a slave terminal of another wafer layer, and cause a slave terminal of the second wafer layer or the slow wafer layer among the three wafer layers to perform data transmission.

In an implementation of the present disclosure, the another wafer layer includes a logic layer and a first storage layer. The second wafer layer or the slow wafer layer among the three wafer layers receives a data storage instruction sent by the logic layer, and the data storage instruction instructs the direct memory access master controller to read data in the first storage layer and store the data in the second wafer layer or the slow wafer layer through the slave terminal of the second wafer layer or the slow wafer layer among the three wafer layers.

In an implementation of the present disclosure, the second wafer layer or the slow wafer layer is a second storage layer, the first storage layer is configured as a volatile storage medium, and the second storage layer is configured as a non-volatile storage medium.

In an implementation of the present disclosure, the logic layer is a wafer layer in the first wafer layer or the third wafer layer provided with a pin.

In an implementation of the present disclosure, the second wafer layer is the first storage layer, and a wafer layer in the first wafer layer or the third wafer layer not provided with a pin is the second storage layer.

In an implementation of the present disclosure, the second wafer layer is the second storage layer, and a wafer layer in the first wafer layer or the third wafer layer not provided with a pin is the first storage layer.

In an implementation of the present disclosure, a pin is led out from the back side of the first wafer layer or the back side of the third wafer layer.

In an implementation of the present disclosure, the three wafer layers are heterogeneously integrated.

In an implementation of the present disclosure, at least one of the three wafer layers is a logic layer, the remaining wafer layers are storage layers, and the logic layer is connected to the pin.

In an implementation of the present disclosure, the first wafer layer includes M first functional units, the M first functional units are interconnected, the second wafer layer includes N second functional units, the N second functional units are interconnected, the third wafer layer includes Q third functional units, the Q third functional units are interconnected, M, N, and Q are natural numbers greater than or equal to 2, and the first functional units, the second functional units, and the third functional units have a same size and are aligned vertically, and are connected through the through-silicon via, the re-distribution layer, and the hybrid bonding.

In an implementation of the present disclosure, any two of M, N, and Q are different.

In an implementation of the present disclosure, the functional units are interconnected through configuration of a programmable connector.

In an implementation of the present disclosure, the programmable connector is configured to provide or cut off a connection between a connecting line in an X-axis direction and a connecting line in a Y-axis direction of a two-dimensional plane where the wafer layer is located.

In an implementation of the present disclosure, the programmable connector is configured to connect an adjacent functional unit to another adjacent functional unit in a same wafer layer, or the programmable connector is configured to connect an adjacent functional unit in the same wafer layer to another adjacent functional unit in an adjacent wafer layer.

In an implementation of the present disclosure, the M first functional units are interconnected through a plurality of first intra-layer routings, the N second functional units are interconnected through a plurality of second intra-layer routings, and the Q third functional units are interconnected through a plurality of third intra-layer routings; and
the M first functional units are connected to the N second functional units through a plurality of first interlayer routings, and the N second functional units are connected to the Q third functional units through a plurality of second interlayer routings.

In an implementation of the present disclosure, the programmable connector of each of the functional units is configured once before an algorithm is executed, and the programmable connector of each functional unit is maintained in a static state during execution of the algorithm.

In an implementation of the present disclosure, the M first functional units and the N second functional units are interleaved and overlaid, and the N second functional units and the Q third functional units are interleaved and overlaid.

According to a second aspect of the embodiments of the present disclosure, a processor is provided, including a processor core and the integrated circuit component according to any one of the foregoing implementations.

According to a third aspect of the embodiments of the present disclosure, a system on chip is provided, including a plurality of processors. Each of the processors is the processor according to the foregoing implementations.

In the solutions of the embodiments of the present disclosure, the integrated circuit component includes three wafer layers, where a front side of a first wafer layer and a front side of a second wafer layer are stacked, and the front side of the second wafer layer and a back side of a third wafer layer are stacked. The three wafer layers are interconnected through a through-silicon via, a re-distribution layer, and hybrid bonding. The second wafer layer or a slow wafer layer among the three wafer layers includes a direct memory access master controller, and the direct memory access master controller is configured to receive a data transmission request sent by a slave terminal of another wafer layer, and cause a slave terminal of the second wafer layer or the slow wafer layer among the three wafer layers to perform data transmission. In the embodiments of the present disclosure, the direct memory access master controller in the second wafer layer or the slow wafer layer causes the data transmission to be performed without the need to cross the three wafer layers, thereby reducing a distance for the data transmission.

### BRIEF DESCRIPTION OF THE DRAWINGS

To describe the technical solutions in embodiments of the present disclosure or the prior art more clearly, the accompanying drawings required for describing the embodiments or the prior art are to be briefly described below. Apparently, the accompanying drawings in the following description merely show some embodiments recorded in the embodiments of the present disclosure, and a person of ordinary skill in the art may still derive other accompanying drawings from these accompanying drawings.

FIG. 1 and FIG. 2 are schematic diagrams of two embodiments of an integrated circuit component.

FIG. 3 is a schematic diagram of data transmission of an existing integrated circuit component.

FIG. 4 is a schematic diagram of data transmission of an embodiment of an integrated circuit component according to the present disclosure.

FIG. 5 is a schematic diagram of an embodiment of an integrated circuit component according to the present disclosure.

FIG. 6a and FIG. 6b are schematic diagrams of yet another embodiment of an integrated circuit component according to the present disclosure.

FIG. 7a and FIG. 7b are schematic diagrams of yet another embodiment of an integrated circuit component according to the present disclosure.

FIG. 8 is a schematic diagram of two embodiments of an integrated circuit component according to the present disclosure.

FIG. 9 is a structural block diagram of a processor according to another embodiment of the present disclosure.

FIG. 10 is a schematic structural diagram of a system on chip according to another embodiment of the present disclosure.

### DETAILED DESCRIPTION

To enable a person in the art to better understand the technical solutions in the embodiments of the present disclosure, the technical solutions in the embodiments of the present disclosure are described clearly and in detail below with reference to the accompanying drawings in the embodiments of the present disclosure. Apparently, the described embodiments are only some rather than all of the embodiments of the present disclosure. Based on the embodiments in the embodiments of the present disclosure, all other embodiments obtained by a person of ordinary skill in the art should fall within the protection scope of the embodiments of the present disclosure.

Reference is made to the accompanying drawings in the following detailed description. These accompanying drawings form a part of the detailed description and illustrate exemplary embodiments. In addition, it should be understood that other embodiments may be utilized and structural and/or logical changes may be made without departing from the scope of the claimed subject matter. It should be further noted that directions and references (for example, up, down, top, or bottom) may be used to facilitate description of features in the accompanying drawings. Therefore, the following detailed description is not to be understood in a limiting sense, and the scope of the claimed subject matter is defined by the appended claims and equivalents thereof.

Numerous details are set forth in the following description. However, it is apparent for a person skilled in the art that the embodiments herein may be practiced without these specific details. In some instances, a well-known method and apparatus are shown in the form of a block diagram rather than in detail to avoid obscuring the embodiments herein. Reference throughout this specification to “an embodiment” or “one embodiment” or “some embodiments” means that a particular feature, structure, function, or characteristic described in connection with the embodiment is included in at least one embodiment herein. Therefore, throughout this specification, the phrase “in an embodiment”, “in one embodiment”, or “in some embodiments” appearing in various places throughout this specification does not necessarily refer to the same embodiment. In addition, in one or more embodiments, a specific feature, structure, function, or characteristic may be combined in any appropriate manner. For example, a first embodiment may be combined with a second embodiment in any case where the particular features, structures, functions, or characteristics associated with the two embodiments are not mutually exclusive.

As used in the description and the appended claims, singular forms “one (a, an)”, and “the” are intended to include the plural forms unless the context clearly indicates otherwise. It is to be further understood that the term “and/or” as used herein refers to and includes any and all possible combinations of one or more of the associated listed items.

Terms “coupled” and “connected”, along with derivatives thereof, may be used herein to describe functional or structural relationships between components. It should be understood that these terms are not as synonyms for each other. On the contrary, in specific embodiments, “connected” may be used to indicate that two or more elements are in direct physical, optical, or electrical contact with each other. The term “coupled” may be used to indicate that two or more elements are in physical or electrical contact directly or indirectly with each other (with another intermediate element between the two elements), and/or that two or more elements cooperate or interact with each other (for example, as in a cause and effect relationship).

As used herein, the terms “over,” “below,” “between,” and “on” refer to a relative position of one component or material with respect to another component or material where such physical relationship is noteworthy. For example, in the context of a material, one material or materials arranged above or below another material may be in direct contact or may have one or more intermediate materials. Moreover, a material arranged between two materials or materials may be in direct contact with two layers or may have one or more intermediate layers. In contrast, a first material or materials “on” a second material or materials are in direct contact with the second material/materials. A similar distinction is performed in the context of component assembly.

As used throughout the description herein and in the claims, a list of items linked by the terms “at least one of” or “one or more of” may mean any combination of the listed items. For example, the phrase “at least one of A, B, or C” may mean A; B; C; A and B; A and C; B and C; or A, B, and C.

A term “circuit” or “module” may refer to one or more passive and/or active components that are arranged to cooperate with each other to provide a desired function. A term “signal” may refer to at least one current signal, voltage signal, or magnetic signal. Terms “substantially”, “near”, “approximately”, “close to”, and “about” generally mean within +/−10% of a target value.

Specific implementations of the embodiments of the present disclosure are further described below with reference to the accompanying drawings of the embodiments of the present disclosure.

A wafer layer (Wafer) is made of pure silicon (Si), and includes a front side and a back side. 3D wafer-level packaging refers to an integrated circuit component encapsulated by more than two wafer layers.

Hybrid bonding (HB, Hybrid bonding) is a method for obtaining a denser interconnection between stacked chips. A hybrid bonding process allows a front side of a wafer to be stacked on another front side.

Through-silicon vias (TSV) primarily function as electrical extension and interconnection on a Z-axis (a coordinate axis perpendicular to a plane where a wafer layer is located).

A re-distribution layer (RDL, Re-distribution Layer) functions as electrical extension and interconnection on an XY plane (a plane where a wafer layer is located). In an advanced packaging technology such as FIWLP (Fan-In Wafer Level Package) and FOWLP (Fan-Out Wafer Level Package), the RDL is adopted. Through the RDL, fan-in or fan-out is performed on an IO pad to form different types of wafer-level packaging.

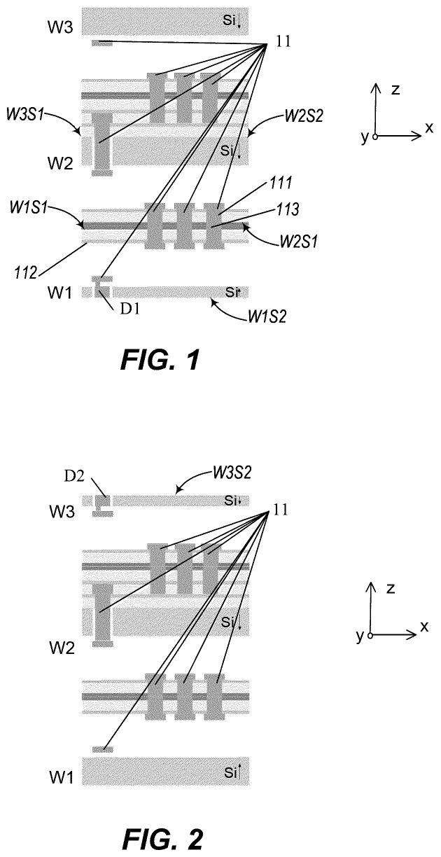

With reference to FIG. 1 and FIG. 2, an embodiment of the present disclosure provides an integrated circuit component, including three chips or dies referred to as wafer layers, W1, W2, and W3. A front side W1S1 of a first wafer layer W1 and a front side W2S1 of a second wafer layer W2 are stacked, e.g., adjacent to one another and coupled together, and the back side W2S2 of the second wafer layer W2 and a front side W3S1 of a third wafer layer W3 are stacked. The three wafer layers W1, W2, and W3 are interconnected through through-silicon vias 111, re-distribution layers 112, and hybrid bonding elements 113. The through-silicon vias 111, the re-distribution layers 112, and the hybrid bonding elements 113 are referred to together as metal mediums 11 for descriptive purposes.

The three wafer layers W1, W2, W3 in an embodiment of the present disclosure are interconnected through the through-silicon vias and the re-distribution layers of each wafer layer W1, W2, W3, and the hybrid bonding elements may be shared between the adjacent wafer layers or may be included in each of the adjacent wafer layers W1, W2, W3, and are coupled together in the interface between adjacent wafer layers. 3D wafer-level packaging of a plurality of wafer layers are achieved through the through-silicon vias, re-distribution layers, and hybrid bonding elements. The integrated circuit component of an embodiment of the present disclosure can provide a larger on-chip storage capacity to meet a requirement for calculation of a foundation model.

FIG. 1 shows a pin D1 led out or exposed from a back side W1S2 of the first wafer layer W1. FIG. 2 shows a pin D2 led out or exposed from the back side W3S2 of the third wafer layer W3. An embodiment of the present disclosure facilitates a pin design of the integrated circuit component.

In an embodiment of the present disclosure, the three wafer layers W1, W2, and W3 may be homogeneously integrated. For example, W1, W2, and W3 are all logic layers. The three wafer layers W1, W2, and W3 may also be integrated heterogeneously. For example, one or more wafer layers of the three wafer layers are different from another wafer layer of the three wafer layers. For example, the first wafer layer W1 is a logic wafer layer, the second wafer layer W2 is an RRAM wafer layer, and the third wafer layer W3 is a DRAM wafer layer.

In an embodiment of the present disclosure, at least one of the three wafer layers is a logic layer, the remaining wafer layers are storage layers, and the logic layer is connected to or includes a pin D1 or D2.

In the integrated circuit component of an embodiment of the present disclosure, the three wafer layers may be designed as logic layers or storage layers based on thermal dissipation requirements. An embodiment of the present disclosure provides a more flexible design scheme.

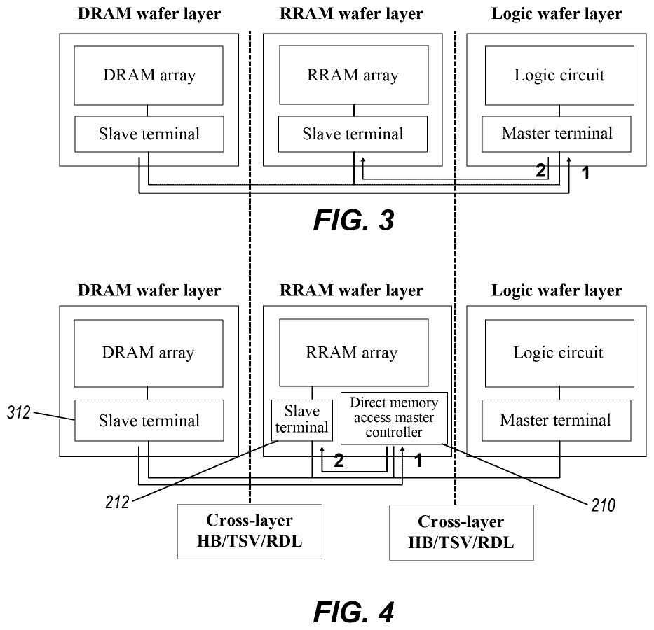

In some descriptions herein, an example in which the first wafer layer W1 is a logic wafer layer, the second wafer layer W2 is an RRAM wafer layer, and the third wafer layer W3 is a DRAM wafer layer is used for illustrative purposes only. Refer to FIG. 3. When a slave terminal of the DRAM wafer layer (e.g., the third wafer layer W3) sends a data transmission request, the data transmission request is sent to the logic wafer layer (e.g., the first wafer layer W1). The logic wafer layer (e.g., the first wafer layer W1) then performs data transmission through a slave terminal of the RRAM wafer layer (e.g., the second wafer layer W2). In this way, the RRAM wafer layer (e.g., the second wafer layer W2) becomes a burden on the logic wafer layer (the first wafer layer W1), and the data transmission needs to cross the three wafer layers, resulting in a long transmission distance.

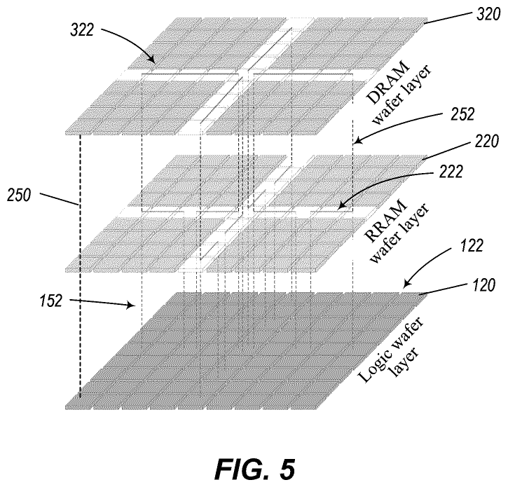

Referring to FIG. 4, in an embodiment of the present disclosure, the RRAM wafer layer (e.g., the second wafer layer W2) includes a direct memory access master controller (DMA Master) 210. When the slave terminal 312 of the DRAM wafer layer (e.g., the third wafer layer W3) sends a data transmission request, the direct memory access master controller 210 in the RRAM wafer layer (e.g., the second wafer layer W2) is configured to receive the data transmission request sent by the slave terminal 312 of the DRAM wafer layer (e.g., the third wafer layer W3), and cause the slave terminal 212 of the RRAM wafer layer (e.g., the second wafer layer W2) to perform data transmission. In an embodiment of the present disclosure, the direct memory access master controller 210 in the second wafer layer releases the burden on the logic wafer layer (e.g., the first wafer layer W1), and causes the data transmission to be performed without the need to cross the three wafer layers W1, W2, W3, thereby reducing a distance for the data transmission.

In an embodiment of the present disclosure, a direct memory access master controller 210 in the second wafer layer W2 causes the data transmission to be performed without the need to cross the three wafer layers, thereby reducing a distance for the data transmission. The second wafer layer W2 refers to a wafer layer stacked in the middle between two wafer layers W1, W3, and the direct memory access master controller 210 enables the processing of data transmission request without having to go through a logic wafer layer (a chip or die having a logic circuitry therein). The second wafer layer W2 does not necessarily to be a RRAM chip or die and can be other types of chips or dies having other functional circuitry therein.

In some embodiments of the present disclosure, the direct memory access master controller (DMA Master) 210 may also be arranged on a slow wafer layer among the three wafer layers. For example, if the third wafer layer W3 among the three wafer layers is an RRAM wafer layer, e.g., a slow wafer layer among the three wafer layers, the direct memory access master controller (DMA Master) 210 can be arranged on the third wafer layer W3. Therefore, through some embodiments of the present disclosure, the slow wafer layer may be prevented from becoming a burden in data transmission, and a speed of data transmission is increased directly through the direct memory access master controller (DMA Master) 210 in the slow wafer layer.

In some examples, another wafer layer includes a logic layer and a first storage layer. The second wafer layer or the slow wafer layer among the three wafer layers receives a data storage instruction sent by the logic layer, and the data storage instruction instructs the direct memory access master controller of the second wafer layer or the slow wafer layer to read data in the first storage layer and store the data in the second wafer layer or the slow wafer layer through the slave terminal 212 of the second wafer layer or the slow wafer layer among the three wafer layers.

In other words, the direct memory access master controller 210 reads data in the first storage layer through the data storage instruction sent by the logic layer, and writes the data in the first storage layer to the second wafer layer or the slow wafer layer.

For example, the second wafer layer W2 or the slow wafer layer (which could be any one of the wafer layers W1, W2, W3) may be configured as an RRAM, and the first storage layer may be configured as a DRAM. The slow wafer layer is a wafer layer that has a slower read or write speed than the logic layer.

In some implementations, the second wafer layer or the slow wafer layer is a second storage layer, the first storage layer is configured as a volatile storage medium, and the second storage layer is configured as a non-volatile storage medium.

In some examples, the logic layer is a wafer layer in the first wafer layer W1 or the third wafer layer W3 provided with a pin D1, D2. The pin is arranged on the wafer layer on a side of a 3D wafer package, which is used for the logic layer to perform efficient read and write operations. In addition, the logic layer is arranged on a side of the integrated circuit component (for example, the 3D wafer package), thereby achieving a better thermal dissipation function.

In some examples, the second wafer layer W2 is the first storage layer, and a wafer layer in the first wafer layer W1 or the third wafer layer W3 not provided with a pin is the second storage layer. When the second storage layer such as the RRAM is the first wafer layer W1 or the third wafer layer W3, the heat dissipation efficiency of the second storage layer is improved, thereby enhancing heat dissipation performance of the integrated circuit component of the wafer level package including wafer layers W1, W2, W3.

In some examples, the second wafer layer is the second storage layer, and a wafer layer in the first wafer layer or the third wafer layer not provided with a pin is the first storage layer. When the second storage layer such as the RRAM is the second wafer layer W2, a data communication delay between the second wafer layer and the logic layer is reduced, thereby improving data transmission efficiency.

It should be understood that each functional unit in the logic layer in the foregoing examples may include a component such as a memory, an ALU, or a controller. When the logic layer is implemented as a processor such as a CPU or an accelerator, the functional unit may be a processor core. The first storage layer may be an array composed of a storage medium, or the first storage layer may be an array composed of another storage medium. The second storage layer herein may further be configured as a storage medium capable of performing in-memory computing.

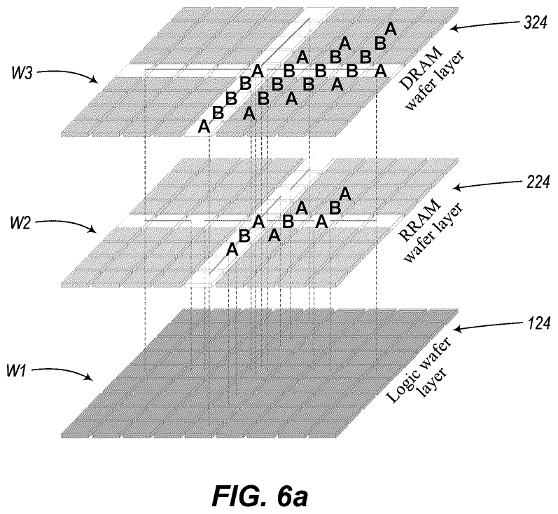

In an implementation of the present disclosure, the first wafer layer W1 in the embodiments of the present disclosure includes M first functional units 120 (FIG. 5), and the M first functional units are interconnected in a number of first intra-layer routings 122. The second wafer layer W2 includes N second functional units 220, and the N second functional units are interconnected in a number of second intra-layer routings 222. The third wafer layer W3 includes Q third functional units 320, and the Q third functional units are interconnected in a number of third intra-layer routings 322. M, N, and Q are natural numbers greater than or equal to 2. The first functional units 120 have a same size among one another, the second functional units 220 have a same size among one another, and the third functional units 320 have a same size among one another. In some implementations, a first functional unit 120, a second functional unit 220, and a third functional unit 320 have the same size and are vertically aligned. Some of the first functional units 120, the second functional units 220, and the third functional units 320 are connected through one or more of through-silicon vias, re-distribution layers, and hybrid bonding elements. Some of the first functional units 120, the second functional units 220, and the third functional units 320 are vertically aligned 250.

In some examples, the M first functional units are interconnected through a plurality of first intra-layer routings 122, the N second functional units are interconnected through a plurality of second intra-layer routings 222, and the Q third functional units are interconnected through a plurality of third intra-layer routings 322. Some of the M first functional units 120 are connected to some of the N second functional units through a plurality of first interlayer routings 152, and some of the N second functional units are connected to some of the Q third functional units through a plurality of second interlayer routings 252. In some implementations, the interlayer routings 152, 252 are achieved through one or more of through-silicon vias, re-distribution layers, or hybrid bonding elements.

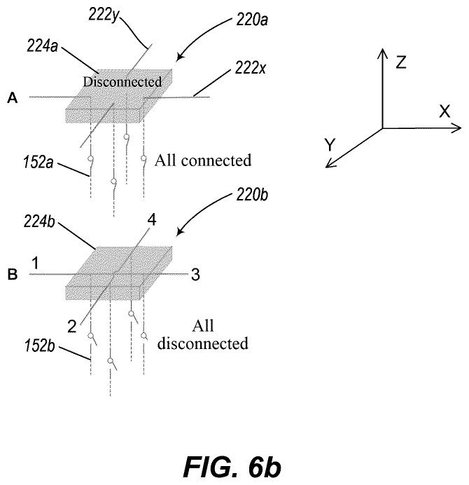

In some embodiments of the present disclosure, the three wafer layers may perform different functions. Referring to FIG. 5, in an illustrative example, the first wafer layer W1 is a logic wafer layer, the second wafer layer W2 is an RRAM wafer layer, and the third wafer layer W3 is a DRAM wafer layer. The logic wafer layer (e.g., the first wafer layer W1) provides control, scheduling, caching, and data transmission between adjacent physical layers. The first wafer layer W1 may include a programmable connector 124 (FIG. 6a). The RRAM wafer layer (e.g., the second wafer layer W2) provides non-volatile storage, a computing function, and a programmable connector 224 (FIG. 6a). The DRAM wafer layer (e.g., the third wafer layer W3) provides a large-capacity main memory and a programmable connector 324 (FIG. 6a).

In some embodiments of the present disclosure, the functional units 120, 220, 320 are interconnected through configuration by respective programmable connectors 124, 224, 324, to facilitate the configuration to implement different connections or disconnections.

In some examples, one or more of the intra-layer routing122, 222, 322 or the inter-layer routing 152, 252 include the programmable connectors that are configured to connect afunctional unit 120, 220, 320 to an adjacent functional unit 120, 220, 320 in a same wafer layer W1, W2, W3, or to connect a functional unit 120, 220, 320 in a wafer layer to an adjacent functional unit 120, 220, 320 in an adjacent different wafer layer.

For example, for an intra-layer routing 122, 222, 322, the programmable connector 124, 224, 324 therein is configured to connect a functional unit 120, 220, 320 to an adjacent functional unit 120, 220, 320 in the same wafer layer. For an interlayer routing 152, 252, the respective programmable connector therein is configured to connect a functional unit in a wafer layer to an adjacent functional unit in an adjacent different wafer layer.

In some implementations, the programmable connector 124, 224, 324 implements the connection of the intra-layer routing 122, 222, 322 through a respective re-distribution layer 112.

The programmable connector implements the connection of the interlayer routing through hybrid bonding elements, or through a combination of one or more of a through-silicon via, a re-distribution layer, or a hybrid bonding member.

It should be understood that each of the functional units 120, 220, 320 may be configured to include a programmable connector 124, 224, 324 (FIG. 6a), or may be configured to implement a corresponding function of the respective wafer layer, for example, a logic computing function (for example, a processor core) or a storage function (for example, a storage cell in a storage array).

In an embodiment of the present disclosure, a connection path across a plurality of functional units is established through each of the three wafer layers W1, W2, W3. When the wafer layer is relatively large in size, low-latency data transmission is performed through the connection path across the plurality of functional units in the wafer layer. In some implementations, the connection path is part of the intra-layer routing 122, 222, 322.

Since the plurality of functional units 120, 220, 320 in each wafer layer W1, W2, W3 are interconnected, if one functional unit in a wafer layer fails due to a problem of manufacturing process yield, a jump to another functional unit may be performed in the wafer layer for data routing and transmission.

In an implementation of the present disclosure, any two of the numbers M, N, or Q are different.

As an example, each intra-layer routing 122, 222, 322 may correspond to a plurality of functional units 120, 220, 320 on a same respective wafer layer. For example, on the first wafer layer W1, m intra-layer routings 122 are distributed in or among the M first functional units 120, and each of the intra-layer routings 122 corresponds to M/m first functional units 120. On the second wafer layer W2, n intra-layer routings 222 are distributed in or among the N second functional units 220, and each of the intra-layer routings 222 corresponds to N/n second functional units 220. On the third wafer layer W3, q intra-layer routings 322 are distributed in or among the Q third functional units 320, and each of the intra-layer routings 322 corresponds to Q/q third functional units 320. In some implementations, M/m=N/n=Q/q.

It should be understood that in an intra-layer routing 122, 222, 322, the functional units 120, 220, 320 within the same wafer layer W1, W2, W3 serve as routing nodes. In an interlayer routing 152, 252, functional units of different wafer layers serve as routing nodes.

In some example implementations, referring to FIG. 6a, M/m=2, e.g., adjacent two first functional units 120 in the first wafer layer W1, e.g., a logic wafer layer, are interconnected. N/n=3, e.g., every 3 second functional units 220 in the second wafer layer W2, e.g., a RRAM wafer layer, are interconnected.

A programmable connector 124, 224, 324 enables various connections and/or disconnections with respect to one or more of the intra-layer routing 122, 222, 322 or the inter-wafer routing 152, 252. Referring to FIG. 6b, in an example implementation of an “A” type configuration of a programmable connector 224a in a second functional unit 220a (or “A” in FIG. 6a), some (4 shown for illustration) downward connected lines 152a (e.g., to the first wafer layer W1), e.g., along the Z-axis direction, are programmed to be connected, which form part of the inter-layer routings 152, and a connecting line 222x in an X-axis direction and a connecting line 222y in a Y-axis direction on a two-dimensional X-Y plane of the second wafer layer W2 where the second functional unit 220a is located are both disconnected.

In an example implementation of a “B” type configuration of a programmable connector 224b in a second functional unit 220b (or “B” in FIG. 6a), downward connected lines 152b are all disconnected, and with respect to the intra-layer routing 222, the programmable connector 224b of the second functional unit 220b is programmed to be connected between nodes 1 and 3 in the X-axis and connected between nodes 2 and 4 in the Y-axis direction. The second functional units 220 may be configured with a programmable connector 224 to be arranged in a form or pattern of A-B-A as shown in FIG. 6a, e.g., two second functional unit 220a with “A” type configuration of the respective programmable connector 224a is connected to one second functional unit 220b (“B”) with “B” type configuration of the respective programmable connector 224b. The programmable connector 224b of the second functional unit 220b is connected in an X-axis direction between nodes 1 and 3 and connected in an Y-axis direction between nodes 2 and 4. For example, one of the second functional unit 220a is connected to node 1 and another second functional unit 220a is connected to node 3 of the second functional unit 220b, and thus the three second functional units 220 arranged in the form or pattern of A-B-A are interconnected.

In some implementations, Q/q is 5, e.g., every 5 third functional units 320 in the third wafer layer W3, e.g., a DRAM wafer layer, are interconnected in an intra-layer routing 322. For example, the programmable connectors 324 in the third functional units 320 may be configured to form an interconnection arrangement in the form of A-B-B-B-A as shown in FIG. 6a. The “A” type and the “B” type configuration of a programmable connector 324 are similar to that of the programmable connector 224a, 224b of the second wafer layer W2, e.g., a RRAM wafer layer, described herein, and the details are not described herein again for brevity purposes.

In some embodiments of the present disclosure, the programmable connectors 124, 224, 324 are configured to provide or cut off a connection between a connecting line in an X-axis direction and a connecting line in a Y-axis direction of a two-dimensional plane where the respective wafer layer W1, W2, W3 is located. Therefore, in some embodiments of the present disclosure, connection or disconnection of functional units of different lengths, e.g., different number of functional units involved in an intra-layer routing, is achieved through connection or disconnection between the connecting lines in the X-axis direction and the connecting line in the Y-axis direction of the programmable connectors 124, 224, 324, so that configuration manners of the embodiments of the present disclosure are more flexible and diverse.

Further, inter-wafer routing or connection 152, 252 among functional units 120, 220, 320 of different wafer layers W1, W2, W3 can also be configured based on the connection or disconnection of connecting lines configured through programmable connectors 124, 224, 324. For example, as shown in FIG. 6b, downward connection lines 152a, 152b of programmable connectors 224a, 224b can be programmed to be connected or disconnected.

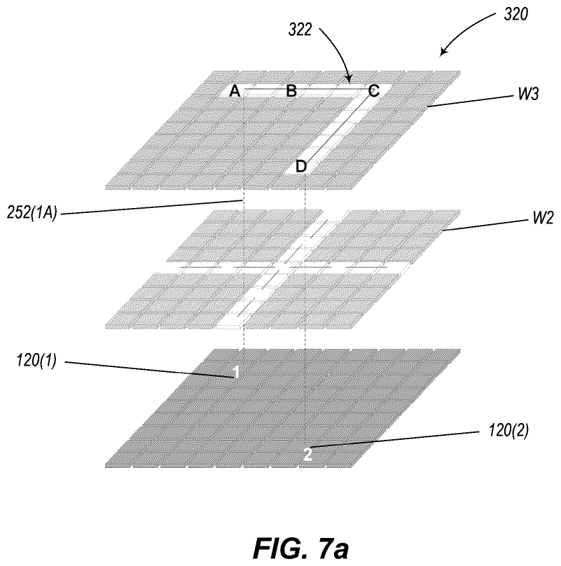

In an example application scenario of an embodiment of the present disclosure, referring to FIG. 7a, during execution of an algorithm, an RRAM wafer layer (e.g., a second wafer layer W2) regularly provides a connection between every 2 second functional units 220, and a DRAM wafer layer (e.g., a third wafer layer W3) dynamically provides a long-distance connection (for example, more functional units 320 are connected on third wafer layer W3). For example, if a first functional unit 120(1) (“1” on FIG. 7a) in a logic wafer layer (e.g., a first wafer layer W1) needs to temporarily transmit data to a first functional unit 120(2) (“2” on FIG. 7a), the DRAM wafer layer (e.g., the third wafer layer W3) may be configured with a data path for transmitting the data. For example, Q/q is set to 4, and 4 third functional units 320 (“A”, “B”, “C”, “D”) are connected. For example, referring to FIG. 7b and FIF. 7a together, programmable connectors 324 of four functional units 320a, 320b, 320c, 320d (A-B-C-D) are connected, through an intra-layer routing 322. Programmable connector 324a of the functional unit 320a is programmed to be downwardly connected to first functional unit 120(1) on the logic wafer layer W1, allowing data sent by the first functional unit 120(1) (“1”) to reach a third functional unit 320d (“D”) on the DRAM wafer layer (e.g., the third wafer layer W3), through the inter-wafer routing and intra-layer routing. Programmable connector 324d of the functional unit 320d is programmed to be downwardly connected to first functional unit 120(2) on the logic wafer layer W1. As such, a data from the first functional unit 120(1) can reach the first functional unit 120(2) (“2”) through the interconnected third functional units 320a (“A”), 320b (“B”), 320c (“C”), and 320d (“D”) of the DRAM wafer layer (e.g., the third wafer layer W3).

In an embodiment of the present disclosure, the programmable connector 124, 224, 324 of each of the functional units 120, 220, 320 is configured once before an algorithm is executed, and the programmable connector of each functional unit is maintained in a static state during execution of the algorithm. Therefore, in the embodiments of the present disclosure, different algorithm functions may be implemented based on the connection of the programmable connector of each functional unit.

In some embodiments of the present disclosure, the M first functional units and the N second functional units are interleaved and overlaid, and/or the N second functional units and the Q third functional units are interleaved and overlaid.

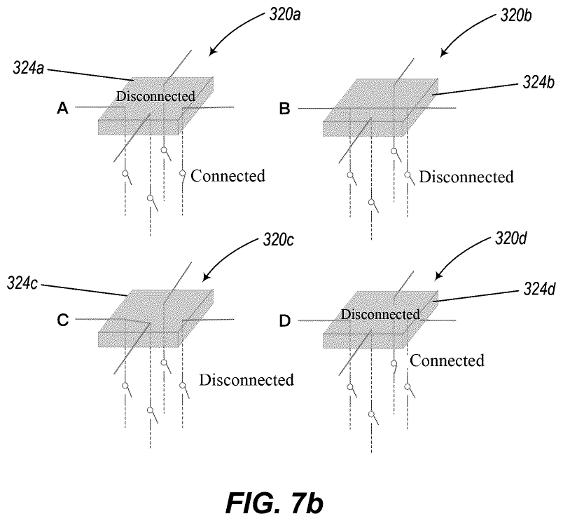

For example, referring to FIG. 8, in some implementations, being interleaved and overlaid means non-aligned overlaying on the functional units 120, 220, 320 in the three wafer layers W1, W2, W3. For example, a third functional unit 320(1) (“1” on FIG. 8) in the DRAM wafer layer (e.g., the third wafer layer W3) corresponds to and is located to overlap a center area 220ca among 4 adjacent second functional units 220, e.g., a second functional unit 220(2) (“2” on FIG. 8), a second functional unit 220(3) (“3” on FIG. 8), a second functional unit 220(4) (“4” on FIG. 8), and a second functional unit 220(5) (“5” on FIG. 8) in the RRAM wafer layer (e.g., the second wafer layer W2), and the programmable connector 324(1) of the third functional unit 320(1) is connected to the respective programmable connectors 224(2), 224(3), 224(4), 224(5) of the second functional unit 220(2), the second functional unit 220(3), the second functional unit 220(4), and the second functional unit 220(5) in the RRAM wafer layer (e.g., the second wafer layer W2) through inter-wafer routings 252(1), e.g., including one or more of through-silicon vias, re-distribution layers, and hybrid bonding elements.

As shown in FIG. 8, the second functional unit 220(5) in the RRAM wafer layer (e.g., the second wafer layer W2) corresponds to a center area 120ca among 4 first functional units 120 in the logic wafer layer (e.g., the first wafer layer W1), e.g., a first functional unit 120(6) (“6” on FIG. 8), a first functional unit 120(7) (“7” on FIG. 8), a first functional unit 120(8) (“8” on FIG. 8), and a first functional unit 120(9) (“9” on FIG. 8), and is also connected to the 4 functional units 120 in the logic wafer layer (e.g., the first wafer layer W1) below. For example, the programmable connector 224(5) of the second functional unit 220(5) is connected to the respective programmable connectors 124(6), 124(7), 124(8), 124(9) of the first functional unit 120(6), the first functional unit 120(7), the first functional unit 120(8), and the first functional unit 120(9) in the logic wafer layer (e.g., the first wafer layer W1) through inter-wafer routings 152(5), e.g., including one or more of through-silicon vias, re-distribution layers, and hybrid bonding elements.

In an example, being interleaved and overlapped can implement data sharing between different functional units. For example, in a case that a calculation result of the first functional unit 120(9) in the logic wafer layer (e.g., the first wafer layer W1) is to be sent to a first functional unit 120(10) (“10” on FIG. 8) for further calculation, the first functional unit 120(9) may transmit the calculation result to the third functional unit 320(1) in the DRAM wafer layer (e.g., the third wafer layer W3) for storage through the second functional unit 220(5) in the RRAM wafer layer (e.g., the second wafer layer W2), and the first functional unit 120(10) in the logic wafer layer (e.g., the first wafer layer W1) obtains the calculation result to continue the calculation from the second functional unit 220(2) in the RRAM wafer layer (e.g., the second wafer layer W2), through respective programmable connector 124(10) and the inter-wafer routing 152 between the programmable connector 124(10) and the programmable connector 224(2). If the second functional unit 220(2) in the RRAM wafer layer (the second wafer layer W2) is busy, the remaining functional units 220 in the RRAM wafer layer (e.g., the second wafer layer W2) connected to the second functional unit 220(2) may be invoked to enable the data transmission between the third functional unit 320(1) and the first functional unit 120(10) for the first functional unit 120(10) to perform calculation. In this case, transmission bandwidth on the logic wafer layer (e.g., the first wafer layer W1) may be saved.

Without loss of generality, the calculation result of a first functional unit 120 in the logic wafer layer is stored in a third functional unit 320 in a first storage wafer layer W3 through an interlayer routing 152 between the logic wafer layer W1 and a second storage wafer layer W2 and an interlayer routing 252 between the second storage wafer layer W2 and the first storage wafer layer W3. A first functional unit 120 in the logic wafer layer W1 may send a write instruction to a second functional unit 220 in the second storage layer W2. The write instruction instructs the second functional unit 220 (for example, a direct memory access master controller) in the second storage wafer layer W2 to read the calculation result from the first storage wafer layer W3 through the interlayer routing 252 between the second storage wafer layer W2 and the first storage wafer layer W3.

It should be understood that a routing node in the interlayer routing between the logic wafer layer W1 and the second storage wafer layer W2 may be determined through an intra-layer routing in the logic wafer layer W1 or an intra-layer routing in the second storage wafer layer W2.

It should be further understood that after the first storage wafer layer W3 is reached, the calculation result may be stored in a target functional unit 320 through the intra-layer routing. Alternatively or additionally, the routing node in the interlayer routing 152 between the logic wafer layer W1 and the second storage wafer layer W2 or a routing node in the interlayer routing 252 between the second storage wafer layer W2 and the first storage wafer layer W3 may be determined through the respective intra-layer routings.

It should be further understood that the routing node in the interlayer routing 252 between the second storage wafer layer W2 and the first storage wafer layer W1 may be determined through the intra-layer routing of the second storage wafer layer W2.

Then the second storage wafer layer W2 may perform in-memory calculation on the calculation result. The logic wafer layer W1 reads an in-memory calculation result through the interlayer routing 152 between the logic wafer layer W1 and the second storage wafer layer W2. Alternatively or additionally, the calculation result is read from the second storage wafer layer W2 through the interlayer routing between the logic wafer layer W1 and the second storage wafer layer based on a read instruction, to continue to perform the calculation or processing.

It should be understood that a routing node in the interlayer routing 152 between the logic wafer layer W1 and the second storage wafer layer W2 may be determined through an intra-layer routing in the second storage wafer layer W2 or an intra-layer routing in the logic wafer layer W1.

Without loss of generality, different functional units 120 in the logic wafer layer W1 may achieve transmission of data (an operand or a calculation result) through the intra-layer routing in the logic wafer layer. Alternatively or additionally, the foregoing data transmission may also be achieved through the interlayer routing 152 between the logic wafer layer W1 and the second storage wafer layer W2 (for example, when calculated load of the logic layer is relatively large). Alternatively or additionally, the foregoing data transmission may also be achieved through the interlayer routing 152 between the logic wafer layer W1 and the second storage wafer layer W2 and the interlayer routing 252 between the second storage wafer layer W2 and the first storage wafer layer W3.

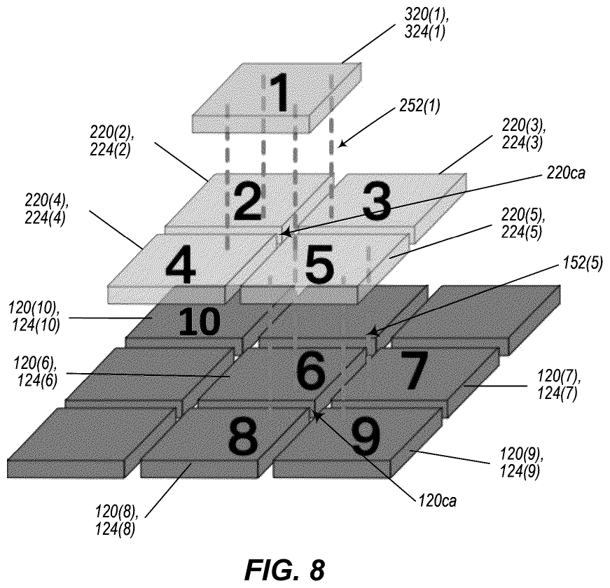

FIG. 9 is a structural block diagram of a processor according to another embodiment of the present disclosure. A processor 900 in an embodiment includes a processor core 901 and an integrated circuit component 902.

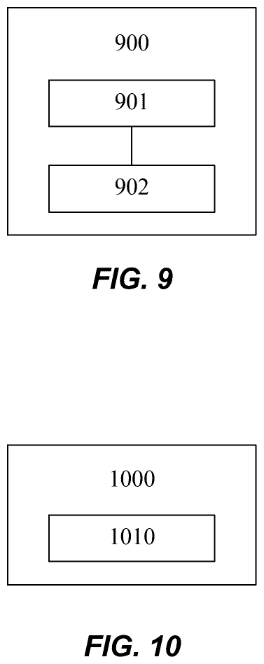

FIG. 10 is a schematic structural diagram of a system on chip according to another embodiment of the present disclosure. A system on chip 1000 in an embodiment includes a plurality of processors 1010.

In addition, for a specific implementation of each step in a program, reference may be made to the corresponding description in the corresponding step and unit in the foregoing method embodiment, and details are not described herein. It may be clearly understood by a person skilled in the art that, for the purpose of convenient and brief description, for a detailed operating process of the foregoing device and module, reference may be made to the description of a corresponding process in the foregoing method embodiment, and the details are not described herein again.

It should be pointed out that according to requirements of implementation, each component/step described in the embodiments of the present disclosure may be split into more components/steps, and two or more components/steps or partial operations of components/steps may be combined into new components/steps to achieve the purposes of the embodiments of the present disclosure.

The foregoing method according to the embodiments of the present disclosure may be implemented in hardware and firmware, or implemented as software or computer code that may be stored in a recording medium (such as a CD ROM, a RAM, a floppy disk, a hard disk, or a magneto-optical disk), or implemented as computer code that is originally stored in a remote recording medium or a non-transitory machine-readable medium and to be stored in a local recording medium and downloaded through a network, so that the method described herein may be stored in such software such as a recording medium using a general-purpose computer, a dedicated processor, or programmable or dedicated hardware (such as an ASIC or an FPGA) for processing. It may be understood that a computer, a processor, a microprocessor controller, or programmable hardware includes a storage component (for example, a RAM, a ROM, and a flash memory) that may store or receive software or computer code. The method described herein is implemented when the software or computer code is accessed and executed by the computer, the processor, or the hardware. Furthermore, when the general-purpose computer accesses code configured for implementing the method shown herein, the execution of the code is to transform the general-purpose computer into a special-purpose computer configured to perform the method shown herein.

A person of ordinary skill in the art may be aware that with reference to the examples described in the embodiments disclosed in this specification, units and method steps can be implemented through electronic hardware or a combination of computer software and electronic hardware. Whether the functions are executed by hardware or software depends on specific applications and design constraint conditions of the technical solutions. A person skilled in the art may use different methods to implement the described functions for each particular application, but it should not be considered that such implementation goes beyond the scope of the embodiments of the present disclosure.

The foregoing implementations are used to describe the embodiments of the present disclosure, but not to limit the embodiments of the present disclosure. Ordinary technicians in the relevant technical fields can make various changes and modifications without departing from the spirit and scope of the embodiments of the present disclosure. Therefore, all equivalent technical solutions also belong to the scope of the embodiments of the present disclosure, and the patent protection scope of the embodiments of the present disclosure shall be defined by the claims.

An integrated circuit component, a processor, and a system on chip are provided in the embodiments of the present disclosure. The integrated circuit component includes three wafer layers, where a front side of a first wafer layer and a front side of a second wafer layer are stacked, and the front side of the second wafer layer and a back side of a third wafer layer are stacked. The three wafer layers are interconnected through a through-silicon via, a re-distribution layer, and hybrid bonding. The second wafer layer or a slow wafer layer among the three wafer layers includes a direct memory access master controller, and the direct memory access master controller is configured to receive a data transmission request sent by a slave terminal of another wafer layer, and cause a slave terminal of the second wafer layer or the slow wafer layer among the three wafer layers to perform data transmission. In the embodiments of the present disclosure, the direct memory access master controller in the second wafer layer or the slow wafer layer causes the data transmission to be performed without the need to cross the three wafer layers, thereby reducing a distance for the data transmission.

What is claimed is:

1. An integrated circuit component, comprising:
a first wafer layer;
a second wafer layer; and
a third wafer layer,
wherein each of the first wafer layer, the second wafer layer and the third wafer layer includes a front side and a back side, the front side of the first wafer layer and the front side of the second wafer layer are stacked, the back side of the second wafer layer and the back side of a third wafer layer are stacked, the first wafer layer, the second wafer layer and the third wafer layer are interconnected through one or more of a through-silicon via, a re-distribution layer, or a hybrid bonding element, a wafer layer of the first wafer layer, the second wafer layer or the third wafer layer includes a direct memory access master controller, and the direct memory access master controller is configured to receive a data transmission request sent by a slave terminal of another wafer layer of the first wafer layer, the second wafer layer or the third wafer layer, and cause a slave terminal of the wafer layer to perform data transmission.

2. The component according to claim 1, wherein the another wafer layer is one or more of a logic layer or a first storage layer; and
the wafer layer is configured to receive a data storage instruction sent by the logic layer, and the data storage instruction instructs the direct memory access master controller to read data in the first storage layer and store the data in the wafer layer through the slave terminal of the wafer layer.

3. The component according to claim 2, wherein the wafer layer is a second storage layer, the first storage layer is configured as a volatile storage medium, and the second storage layer is configured as a non-volatile storage medium.

4. The component according to claim 3, wherein the logic layer is the first wafer layer or the third wafer layer and includes a pin.

5. The component according to claim 4, wherein the second wafer layer is the first storage layer, and a wafer layer of the first wafer layer or the third wafer layer that does not includes a pin is a second storage layer.

6. The component according to claim 4, wherein the second wafer layer is the second storage layer, and a wafer layer in the first wafer layer or the third wafer layer that does not includes a pin is the first storage layer.

7. The component according to claim 1, wherein a pin is exposed from the back side of the first wafer layer or the back side of the third wafer layer.

8. The component according to claim 7, wherein the first wafer layer, the second wafer layer, and the third wafer layer are heterogeneously integrated.

9. The component according to claim 8, wherein at least one of the first wafer layer, the second wafer layer, or the third wafer layer is a logic layer, remaining wafer layers of the first wafer layer, the second wafer layer or the third wafer layer are storage layers, and the logic layer is connected to the pin.

10. The component according to claim 9, wherein:
the first wafer layer includes M first functional units each of a same first size, and each of the M first functional units is interconnected with another one of the M first functional units,
the second wafer layer includes N second functional units each of a same second size, and each of the N second functional units are interconnected with another one of the N second functional units,
the third wafer layer includes Q third functional units each of a same third size, and each of the Q third functional units are interconnected with another one of the Q third functional units, M, N, and Q being natural numbers greater than or equal to 2, and
the first functional units, the second functional units, and the third functional units are connected through the through-silicon via, the re-distribution layer, and the hybrid bonding member.

11. The component according to claim 10, wherein any two of M, N, or Q are different.

12. The component according to claim 10, wherein the first functional units, the second functional units, and the third functional units are interconnected through configurations of programmable connectors.

13. The component according to claim 12, wherein a programmable connector of the programmable connectors is configured to provide or cut off a connection between a connecting line in a lateral direction of a two-dimensional plane where a respective wafer layer is located.

14. The component according to claim 13, wherein the programmable connector is configured to connect a functional unit to an adjacent functional unit in a same wafer layer, or the programmable connector is configured to connect a functional unit in the same wafer layer to an adjacent functional unit in an adjacent wafer layer.

15. The component according to claim 10, wherein the M first functional units are interconnected through a plurality of first intra-layer routings, the N second functional units are interconnected through a plurality of second intra-layer routings, and the Q third functional units are interconnected through a plurality of third intra-layer routings; and
the M first functional units are connected to the N second functional units through a plurality of first interlayer routings, and the N second functional units are connected to the Q third functional units through a plurality of second interlayer routings.

16. The component according to claim 12, wherein the first functional units, the second functional units, and the third functional units each includes a programmable connector, the programmable connect of the each of the first functional units, the second functional units, and the third functional units is configured once before an algorithm is executed, and the programmable connector of each of the first functional units, the second functional units, and the third functional units is maintained in a static state during execution of the algorithm.

17. The component according to claim 10, wherein the M first functional units and the N second functional units are interleaved and overlaid, or the N second functional units and the Q third functional units are interleaved and overlaid.

18. The component according to claim 12, wherein a programmable connector of the programmable connectors is configured to provide or cut off a connection between a connecting line in a vertical direction between a wafer layer where the programmable connector is located and an adjacent wafer layer.

19. A processor, comprising:
a processor core; and
an integrated circuit component, the integrated circuit component including:
a first die including a plurality of first functional units interconnected to one another through first programable connectors of the plurality of first functional units; and
a second die including a plurality of second functional units interconnected to one another through second programable connectors of the plurality of second functional units,
wherein a first programable connector of the first programable connectors is connected to a second programable connector of the second programable connectors.

20. A system on chip, comprising:
a plurality of processors, each of the processors including a processor core and an integrated circuit component, the integrated circuit component including:
a first die including a plurality of first functional units each including a first programable connector; and
a second die including a plurality of second functional units each including a second programable connector,
wherein a first programable connector of the first die is connected to a second programable connector of the second die.
